(19) United States
(12) Patent Application Publication
(10) Pub. No.: US 2026/0173272 A1
(43) Pub. Date: Jun. 18, 2026

(54) REMOVABLE VOLTAGE REGULATOR MODULE

(71) Applicant: HEWLETT PACKARD ENTERPRISE DEVELOPMENT LP, Spring, TX (US)

(72) Inventor: Mohamed Amin Bemat, Cypress, TX (US)

(21) Appl. No.: 18/980,848

(22) Filed: Dec. 13, 2024

(51) Int. Cl. H05K 1/18; H02M 3/00; H05K 1/11

(52) U.S. Cl. CPC H05K 1/181; H02M 3/003; H05K 1/11; H05K 2201/10742

(57) ABSTRACT

A voltage regulator module and a circuit board of an information processing device can be removably connected together via a reversible mechanical connection. The voltage regulator module comprises a printed circuit board (PCB), voltage regulator components mounted to one face of the PCB, and electrical contacts arranged as concentric rings in an opposite face of the PCB and electrically connected to the voltage regulator components through the PCB. The module also comprises at least one attachment feature configured to removably attach the module to the circuit board. The concentric rings are arranged to contact solder balls arranged in a complementary pattern on a face of the circuit board, thereby electrically connecting the module to the circuit board. The contact between the rings and the solder balls may be simple mechanical contact without any soldered (i.e., braised or welded) bond formed between the solder balls and the rings.

### INTRODUCTION

Information processing systems often use various analog and digital control circuits for system operation and functions. These may include voltage regulator components which may regulate or control a flow of electricity, such as by converting it from one voltage to another. For example, voltage regulator components may be configured as so-called voltage regulator modules (VRM) mounted on a system board for regulating the voltage received by the system board, such as from a power supply unit (PSU), and the voltage supplied to various components of the system, such as a central processing unit (CPU), due to the voltage required by those components differing from the voltage supplied by the power unit. These VRMs may include one or more transistors and a power controller to control the transistors, as well as various other electrical components in some cases. As another example, voltage regulator components may be arranged within power supply unit (PSU) of the information processing device to regulate power flows within the PSU and/or otherwise control functions of the PSU. For example, a PSU may have one or more converters (e.g., AC-DC converter, DC-DC converter, etc.) to convert the power received from outside the system into a different form more suitable for use in the system, such as converting 120 V AC input into 12V DC which is output to the system board. The system board may then use its own VRM to regulate to a lower voltage, such as a 3.3V provided to a CPU. The converters in the PSU may have their own power controllers which control their operations.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operation. In the drawings:

FIG. 1 is a block diagram illustrating an example of a voltage regulator module installed in an example circuit board of an information processing system.

FIG. 2A is a schematic cross-sectional diagram illustrating an example of a voltage regulator module prior to being installed in an example circuit board of an information processing system.

FIG. 2B is a schematic cross-sectional diagram illustrating an assembly of the voltage regulator module and circuit board in an assembled state.

FIG. 3 is a block diagram illustrating an example information processing system including solder balls connectors.

FIG. 4A is a bottom view of example concentric rings of a voltage regulator module.

FIG. 4B is a top view of example solder balls of a circuit board of an information processing system.

FIG. 5A is a bottom view of another example concentric rings of a voltage regulator module that includes a keying hole.

FIG. 5B is a top view of example solder balls of a circuit board of an information processing system that includes a keying pin.

The drawings are included to provide a further understanding of the present disclosure and are incorporated in and constitute a part of this specification. The drawings illustrate one or more examples of the present teachings and together with the description explain certain principles and operations. In some cases, details that are not necessary for an understanding of an instance of this disclosure or that render other details difficult to perceive may have been omitted.

### DETAILED DESCRIPTION

In many systems, the VRMs are directly soldered to a primary system board of those systems. Due to the difficulty of replacement of those soldered VRMs, their useful life is often limited to the life of the board, and vice-versa as often a system board needs to be replaced when the VRM fails. Similarly, the power management controllers with supporting electrical components in a PSU are generally directly soldered to the main board of the PSU, and thus they are also difficult to replace and the failure of one generally results in the disposal of the other. To make it easier to replace voltage regulators, some systems may disposed the voltage regulator on an expansion board which is distinct from the main circuit board of the system, with the expansion board being connected to the system board through an edge connector of the expansion board mating with a socket of the system board. This approach is often limited due to the cost. For example, the gold finger connector of the edge connection creates an increased cost of using the VRM through the edge connector, as opposed to using an embedded VRM. Another issue with this approach is the space constraint of the host system. The socket connector required on the system side to receive the edge connector of the expansion card carrying the VRM would require space and cost.

To address the above issues, presented in this disclosure is a voltage regulator module that is configured to be connected to a host board (e.g., primary system board of a system or circuit board of a PSU) in an easily removable manner without the use of an edge connector. In particular, the voltage regulator module is connected to the host board through a patterned contact pad connector on a face of a PCB of the controller module which contacts a complementary pattern of electrical contacts located on the face of the host board. The patterned contact pad connector comprises a set of electrical contact pads (e.g., exposed traces) arranged in a planar (two-dimensional) pattern and which are configured to removably contact and electrically connect with the electrical contacts of the host board in a reversible manner, meaning that there is no adhesive or welded/braised/soldered connection that would resist the separation of the traces from the contacts. Instead, the connection between the contact pads of the module and the contacts of the host board is maintained by virtue of the module being mechanically fastened to the host board by a releasable fastener, such as a screw or latch. The controller module includes printed circuit board (PCB) that includes the electrical contact pads on one side electrically connected to a microcontroller, such as a microcontroller of a VRM, located on the opposite side. The two-dimensional pattern of the electrical contact pad of the voltage regulator module may include a set of concentric rings, and the electrical contacts of the host board may thus be arranged in a complementary set of concentric rings. Because this approach connects to the system board through a PCB, other modules besides a VRM can also be used.

The electrical contacts of the host board may include solder balls which are formed on (i.e., soldered to) contact pads on the face of the system board. These solder balls contact the electrical contact pads on the PCB of the voltage regulator module to electrically connect the voltage regulator module to the host board. Note that, although solder is present, the solder is not welded or braised to the electrical contact pads of the PCB of the module and thus a true “soldered” joint therebetween is not formed. Thus, the connection is easily reversible.

This approach provides a lower cost of usage, since the modules can easily be replaced without replacing other components of the system, through the use of the patterned contact pads (i.e. concentric rings) that connects to soldered balls on the face of the host board. Also, because this approach uses a PCB that is vendor and module type agnostic, this approach enables the use of multiple vendors and multiple types of modules.

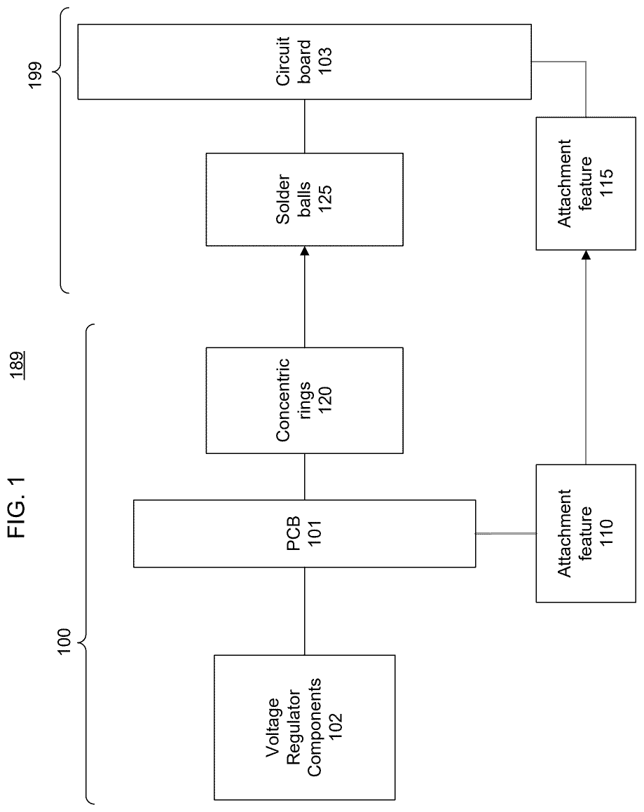

These and other examples will be described in greater detail below in relation to FIGS. 1-5.

Now referring to FIG. 1, an assembly 189 including a voltage regulator module 100 and an information processing system 199 is presented. Voltage regulator module 100 is a removable module configured to be removably installed in information processing system 199, such as a server, networking device, or other information processing system. In particular, voltage regulator module 100 is configured to removably connect to a circuit board of an information processing system. Specifically, voltage regulator module 100 connects the to the information processing system using electrical contacts arranged as concentric rings removably connected to solder balls attached to the circuit board of the information processing system, as will be described in greater detail below. Although voltage regulator module 100 and information processing system 199 are described together herein for ease of understanding, it should be understood that components of controller module 100 and/or components of information processing system 199 may be produced or sold separately or together and may be claimed separately or together herein. In FIG. 1, electrical connections are indicated by solid lines (not all connections are necessarily shown), whereas permanent, or semi-permanent, attachment are indicated by solid double lines. Lines with arrows thereon indicate removable electrical connections, whereas double lines with arrows indicate removable attachment.

Voltage regulator module 100 includes a printed circuit board (PCB) 101 and voltage regulator components 102 mounted to the PCB 101. “Voltage regulator components” as used herein refers to electrical components configured as electrical functional circuit designed and configured to regulate flow of electrical power within an electronic device, such as by performing power management control tasks. Voltage regulator components 102 may include microcontroller, power mosfets, passive components like resistor, capacitors and magnetic components like inductors and transformers. In some examples, voltage regulator components 102 may be arranged for use as a VRM configured to receive power from a PSU and deliver regulated power to a CPU or other component of an information processing system. In some examples, voltage regulator components 102 may be arranged for use as control circuitry in a PSU configured to control aspects of operations of the PSU, such as controlling a power conversion within the PSU.

Voltage regulator module 100 also includes an attachment feature 110 configured to removably attach the voltage regulator module 100 to a circuit board 103 of the information processing system 199. In instances, attachment feature 110 is configured to maintain voltage regulator module 100 in a secured and electrically connected state with circuit board. In instances, attachment feature 110 may include eversible mechanical attachment features, such as reversible fasteners (e.g., screws), threaded apertures, clips, clamps, and the like.

The voltage regulator module 100 also includes a set of electrical contact pads (e.g., exposed electrical traces in the PCB or contact pads formed on the surface of the PCB) formed into a pattern of concentric rings 120 on one side of the PCB 101. As used herein, the “concentric rings” are rings that share the same center point but have different radius. Voltage regulator components 102 are electrically connected to PCB 101 via additional electrical contacts (not illustrated) on an opposite side of the PCB 101. PCB 101 includes electrical pathways connecting the concentric rings 120 to the voltage regulator components 102. In instances, concentric rings 120 may be solid metal (e.g., copper) rings. In some instances, concentric rings 120 may be gold plated or tin plated. In instances, concentric rings 120 may be flush with a surface of the PCB 101. References herein to “ring” include, but are not limited to, a ring with a circular profile. While a circular profile ring may have some advantages, as explained below, concentric rings 120 may have other shapes in some examples, such squared shaped, or polygonal shaped, etc. In some instances, concentric rings 120 may be formed integrally with the PCB 101 (i.e., as exposed traces of the PCB), for example via etching, deposition, or any other PCB manufacturing techniques. In instances, concentric rings 120 may be formed separately from the PCB 101 and then later joined thereto, such as by being soldered to PCB 101 or being press fitted into PCB 101. For example, PCB 101 may be manufactured with a ring shaped plated recesses, apertures, or through-holes into which the rings 120 are inserted.

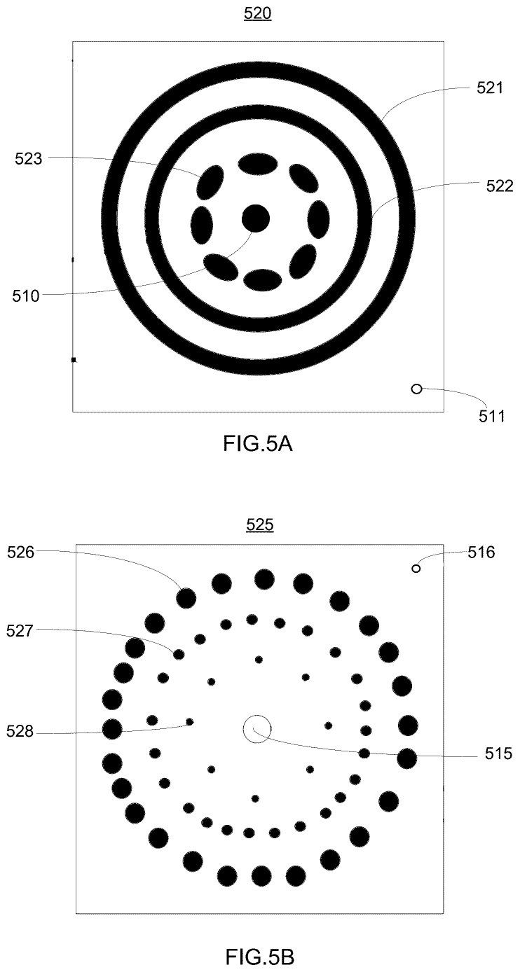

In instances, some or all of the concentric rings 120 may form a continuous ring without any breaks. In some instances, one or more of the concentric rings 120 may be a dotted (i.e., broken, discontinuous) ring, meaning the ring 120 comprises a series of segments arranged in a path which follows the general shape of a ring but with occasional breaks between the segments. For example, assuming a circular ring shape, a dotted ring may comprise a collection of segments arranged in a circle with breaks between adjacent segments. In some examples, continuous rings and dotted rings may be used together, such as using continuous rings for transfer of power signals and dotted rings for transfer of data signals. An example of the dotted concentric ring is provided in reference to FIG. 5A. In some examples, only continuous rings 120 are used.

The information processing system 199 includes the circuit board 103 and solder balls 125 permanently attached, and electrically connected, to the circuit board 103. In some examples, circuit board 103 may be a primary system board, such as a motherboard or host processor module (HPM). In other examples, circuit board 103 may be a power supply unit (PSU) board, and the like. The “solder balls” as used herein are lumps (e.g., spheres) of solder material connected (e.g., soldered) to electrical contacts on a face of the circuitry board 103. In instances, solder balls 125 may protrude from the face of the circuit board 103. This may allow the solder balls 125 to contact concentric rings 120 that are flush with the face of the PCB 101. It should be noted that for concentric rings 120 that are solid continuous rings, not all solder balls 125 need to contact the respective concentric ring 120 for a connection to be established. For example, if a set of solder balls 125 that are in contact with the respective concentric ring 120 are sufficient to transfer, or receive, the required voltage for their use case, then the connection is established even if some of the solder balls 125 of that set are not in contact with the ring.

In instances, solder balls 125 are arranged in a pattern comprising a set of concentric dotted rings, with each solder ball 125 forming a segment (or “dot”) of the dotted ring. Each dotted ring of solder balls 125 corresponds to, and is configured to make contact with, one of the concentric rings 120 of the voltage regulator module 100. Thus each dotted ring of solder balls 125 is arranged to have the same diameter and same shape as the corresponding concentric ring 120. In some instances, solder balls 125 are arranged in a non-circular dotted pattern. It should be noted that the dotted pattern can have any pattern, as long as that pattern can make sufficient contact to establish a connection with the concentric rings 120.

The information processing system 199 may include a second attachment feature 115 configured to engage with attachment feature 110 as to removably attach the voltage regulator module 100 to the circuit board 103. In an example, each of attachment features 110 and 115 may be threaded apertures, where the voltage regulator module 100 is removably attached to the circuit board 103 through a fastener being fastened through both threaded apertures. In an example, attachment feature 110 may be a clamp while attachment feature 115 may be a protrusion configured to engage with the clamp, or vice versa. It should be noted that first and second attachment features 110/115 may include other types of attachments not described herein. For example, attachment features 110/115 may be a lever system that can be used for locking and releasing voltage regulator module 100 to and from circuit board 103.

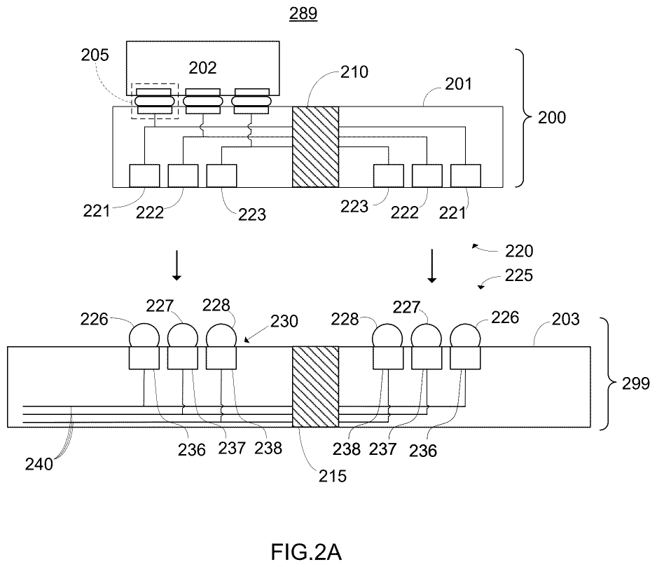

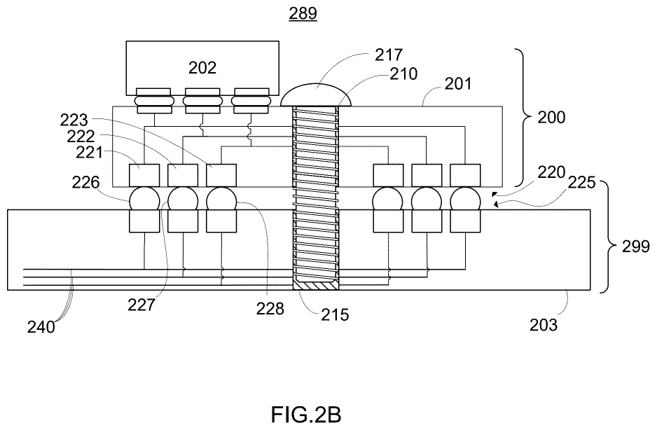

Now referring to FIGS. 2A and 2B, an example assembly 289 is presented. This example illustrates the connection of a voltage regulator module 200 with an information processing system 299. In FIG. 2A, the module 200 and system 299 are shown in the processes of being assembled before assembly is complete, whereas FIG. 2B illustrates the assembly 289 in an assembled state. Assembly 289 may be an implementation example of, or include, assembly 189. As such, Voltage Regulator module 200 and information processing system 299 may be the same as Voltage Regulator module 100 and information processing system 199, respectively. Elements in FIG. 2 whose reference numbers have the same last two digits as elements described above in reference to FIG. 1, such as 120 and 220, correspond to one another, meaning the element in FIG. 2 is the same as, or an implementation example of, the corresponding element in FIG. 1.

Voltage regulator module 200 includes a PCB 201 and voltage regulator components 202 mounted to the PCB 201. Voltage regulator module 200 also includes concentric rings 220 electrically connected to voltage regulator components 202. More specifically, voltage regulator components 202 comprise one or more electrical components electrically connected to the PCB 201 and the concentric rings 220 via electrical interfaces 205. FIG. 2A illustrates the electrical interfaces 205 in the style of contact pads joined via soldered connections, but this is just one example and any other desired electrical interfaces may be used as the electrical interfaces 205, such as pins inserted through holes or any other interface. The electrical interfaces 205 are electrically connected to the rings 220 via internal circuitry (e.g., conductive traces) of the PCB 201.

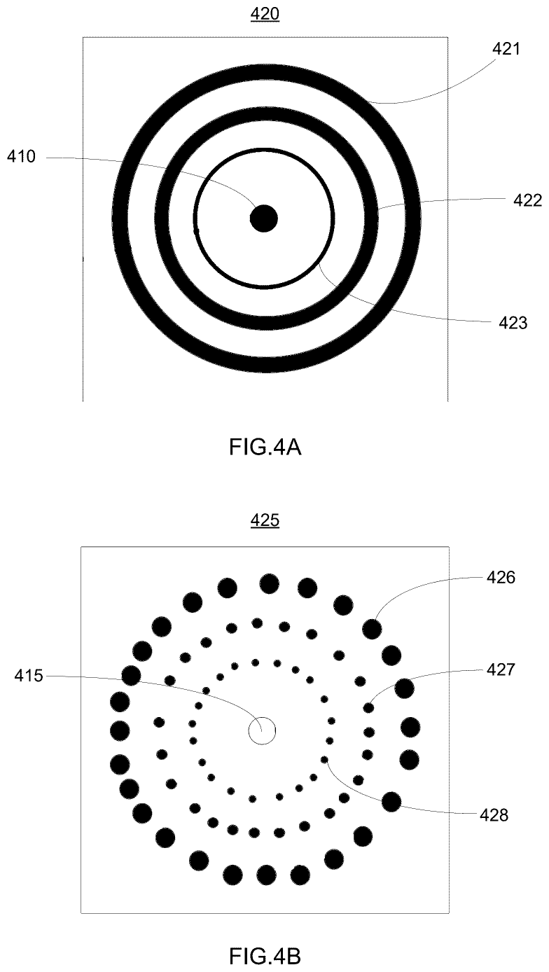

Concentric rings 220 includes a first set of electrical contacts arranged in a first ring 221, a second set of electrical contacts arranged in a second ring 222 and a third set of electrical contacts arranged in a third ring 223. FIGS. 2A and 2B depict the rings 220 schematically as if in cross-section, but if the module 200 were viewed from below in a bottom view, the rings 220 may have an appearance such as is illustrated in FIG. 4A or 5A, for example, which will be described in greater detail below. Rings 220 are arranged to contact corresponding solder balls 225 on circuit board 203 when module 200 is assembled to circuit board 203, as will be explained in greater detail below.

First and second rings 221/222 are solid continuous rings. In instances, the third ring 223 may be a solid ring, such as in the example of FIG. 4A. In instances, the third ring 223 may be a dotted ring, such as in the example of FIG. 5A. In an example in which the third ring 223 is a dotted ring, the ring 223 comprises a series of electrical contacts arranged in dotted ring configuration, and each such electrical contact may be configured to be aligned with a respectively corresponding solder ball, or corresponding group of solder balls, of the solder balls 225. Contact between the rings 221, 222, and 223 and the corresponding solder balls 225 establishes an electrical connection therebetween, which electrically connects the voltage regulator components 202 to system 299.

For rings in a sold ring configuration, such as first and second rings 221/222 in both FIGS. 4A and 5A, and third ring 223 in FIG. 4A, the electrical connection for each ring 220 may be established by the contact of any portion of the ring with one or more corresponding solder balls.

Information processing system 299 includes a circuit board 203. Circuit board 203 includes internal electrical traces 240 which include power rails and communication traces. As used herein, power rails are electrical pathways designed and configured to distribute electricity at specific voltage levels from a power source, such as a PSU, to various components of the system. In the example of FIG. 2, power rails are used to distribute a voltage from a PSU to the voltage regulator module 200. Power rails include, in some examples a supply power rail which carries a supply voltage (e.g., 12V) and a ground power rail which carries the ground voltage, thus forming a voltage difference between these rails equal in magnitude to the supply potential. The internal electrical traces 240 may further include a communication trace. Circuit board 203 includes a plurality of electrical contacts 230 (aka contact pads) at the face of circuit board 203. The electrical contacts are electrically connected to the internal electrical traces 240. In some examples, the contacts 230 are arranged in groups corresponding, respectively, to the rings 220, including a first group 236 corresponding to first ring 221, a second group 237 corresponding to second ring 222, and a third group 238 corresponding to third ring 223. In some examples, each group of contacts 230 may be arranged in ring is similar to the corresponding concentric ring 220—for example, the first group 236 may be arranged in a broken ring with similar diameter as the first ring 221, the second group 237 may be arranged in another broken ring with diameter similar to the second ring 222, and the third group 238 may be arranged in another ring with diameter similar to the third ring 223.

Circuit board 203 includes a plurality of solder balls 225 formed on the contacts 230. Solder balls 225 includes a first set of solder balls 226 formed on the first group 236 of electrical contacts 230 of the circuit board 203. In instances, the first set of solder balls 226 may be electrically connected to a supply voltage power rail of the internal electrical traces 240. Circuit board 203 further includes a second set of solder balls 227 formed on the second group 237 of electrical contacts 230 of the circuit board 203. In instances, second set of solder balls 227 may be electrically connected to a ground power rail of the internal electrical traces 240. Solder balls 225 includes a third set of solder balls 228 formed on the third group 238 of electrical contacts 230 of the circuit board 203. In some instances, third set of solder balls 228 may be electrically connected to the ground or supply voltage power rail of the internal electrical traces 240. In instances, third set of solder balls 228 may be electrically connected to the communication trace or control signal of the internal electrical traces 240. It should be noted that the solder balls 225 are shown schematically as if in a side view for ease of illustration. As such, a person of ordinary skill in the art would readily understand that each of the sets of solder balls 225 includes a plurality of solder balls arranged in a dotted ring arrangement, such as is shown in FIGS. 4B and 5B.

In many examples, the solder balls 225 are arranged in rings corresponding to the rings 220 and each such ring of solder balls 225 may include multiple solder balls 225 (see, for example, FIGS. 4B and 5B). This can allow for multiple solder balls 225 to contact a single ring 220. The more solder balls 225 that contact a given ring 220, the better the electrical connection (i.e., the lower the resistance) with that ring 220, which is why it may be desired, in some circumstances, to provide multiple solder balls 225 for a single ring 220. However, it should be understood that not necessarily all solder balls 225 provided for a given ring 220 necessarily have to make contact with the ring 220 in order for a suitable electrical connection to be made. For continuous rings, each ring 220 may generally carry one individual electrical signal at a time.

For rings 220 in a dotted ring configuration, such third ring 223 in FIG. 5A, each segment of the ring 220 may need to make contact with at least one solder ball 225 in order to establish an electrical connection to that segment. In some cases, one solder ball is provided per segment. In other cases, multiple solder balls may be provided per segment. In some examples, in which a dotted ring 220 is present, different segments of a dotted ring 220 may carry different electrical signals. In other words, it is possible for a given ring 220 in a dotted configuration to carry multiple different electrical signals simultaneously. This can allow for the number of signals which pass through the interface to be multiplied without necessarily increasing the number of rings 220. However, because fewer solder balls may contact each segment in a dotted ring, as compared to the number of solder balls that contact a single continuous ring, a resistance for a given segment may be somewhat higher than for a given continuous ring. Thus, in some instances, the dotted ring configuration may be better suited for some applications where the higher resistance is acceptable.

For example, in some implementations the dotted ring configuration may be used for carrying data or control signals, wherein the contacts (segments) of the dotted ring are arranged in groups of one or more segments and each group may carry a separate signal (e.g., in some cases, a group may comprise a pair of segments each carrying one half of a differential signal). In such cases, alignment of each contact (segment) of the dotted ring 220 with the correct corresponding solder ball 225 may be important in order to ensure the contacts receive the desired signals from the correct solder balls. This may require control over the angular orientation of the module 200 relative to the PCB 203 in a plane parallel to the face of the PCB 203. Thus, in some examples in which rings 220 in a dotted configuration are used, alignment guides may be needed, as discussed below.

On the other hand, in some implementations the solid ring configuration may be used for electrical signals for which lower resistance is desired, such as to transfer power. In some examples in which all rings 220 have a solid configuration, the angular orientation of the module 200 relative to the PCB 203 in the plane parallel to the face of the PCB 203 may not matter because each continuous ring 220 carries but one signal at a time and thus the particular location on a given ring 220 at which each corresponding solder ball 225 contacts the ring 220 doesn't affect anything.

Voltage Regulator module 200 includes an attachment feature 210, while circuit board 203 includes a second attachment feature 215. As described in reference to FIG. 1, Voltage Regulator module 200 is removable attached to circuit board 203 via an attachment of attachment feature 210 to second attachment feature 215. For example, attachment feature 210 and second attachment feature 215 may be threaded apertures, which are attached to each other by a fastener 217, such as a screw that is fastened through both attachments features 210 and 215, as shown in FIG. 2B.

Note that, in the attached state shown in FIG. 2B, the solder balls 225 are merely in mechanical contact with the rings 220, but the solder balls 225 and rings 220 are not joined or bonded together such as by welding/brazing/soldering. In other words, even though solder is present, this is not a traditional “soldered” joint because the solder has not been melted or reflowed to form a joint with the rings 220. Thus, disconnection of the rings 220 from the solder balls 225 does not require the application of heat to melt the solder or the use of destructive techniques to break bonds therebetween. Instead, the rings 220 can be separated from the solder balls 225 by simply detaching the attachment feature 210 and 215 from one another (e.g., removing screw 217) and then the application of de minimus force to pull the module 200 away from the board 203.

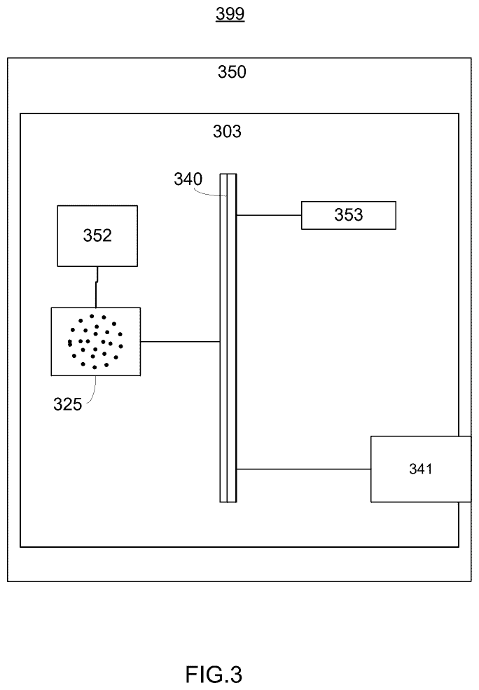

Now referring to FIG. 3, an example information processing system 399 is presented. Information processing system 399 may be an implementation example of, or include, information processing system 199/299 described in reference to FIGS. 1 and 2. Information processing system 399 includes a chassis 350, a primary system board 303 supported by the chassis 350 and a power supply unit (PSU) 341 electrically connected to the primary system board 303. A “chassis,” as used herein, is an enclosure designed to house and support hardware components. In instances, PSU 341 may be supported by the chassis, such as by a rear panel of the chassis 350.

In instances, information processing system 399 includes a processor 352 mounted to the primary system board 303. As used herein, a “processor” is a component configured for executing instructions, performing calculations and managing tasks. In instances, information processing system 399 may include two or more processors 352 mounted to primary system board 303. In an example, without limitations, processor 352 may be a Central Processing Unit, (CPU).

In instances, information processing system 399 includes at least a memory 353 mounted to primary system board 303. As used in this disclosure, a “memory” is a data storage component configured to store instructions for a computing component, such as processor 352. In examples, without limitations, memory 353 may be configured for temporary storage of data, such as a random-access memory (RAM), or permanent data storage, such as Solid-State drives (SSD).

In instances, information processing system 399 includes internal electrical traces 340. The internal electrical traces 340 include power rails and communication traces. In instances, PSU 341 is electrically connected to primary system board 303 via internal electrical traces 340. In an example, internal electrical traces 340 may receive 12 v voltage level from PSU 341 and distribute the 12V power to a plurality of components of primary system board 303. In instances, information processing system 399 includes solder balls 325 mounted to primary system board 303 and electrically connected to internal electrical traces 340.

Information processing system 399 is configured to receive a voltage regular module (VRM), not shown, connected to solder balls 325 as to regulate the voltage from the PSU 341, via internal electrical traces 340, to processor 352. Voltage regulator module is referenced to in FIGS. 1 and 2. For example, the voltage regulator module connected to solder balls 325 may receive a 12 v from internal electrical traces 340 and transmit a 3.3 v to processor 352. In one example, one set of solder balls 325 may transfer 12 v power from the internal electrical traces 340 to the voltage regulator module and another set of solder balls 325 may transfer regulated 3.3 v power from the voltage regulator module to processor 352. It should be noted that although only one connecting set of solder balls 325 is shown for ease of description, multiple connection sets of solder balls 325 may be included in information processing system 399. Each connection set refers to a set of solder balls 325 configured to receive a module. In instances, multiple connection sets of solder balls 325 may be mounted to primary system board 303. For example, multiple connection sets of solder balls 325 may be used for connecting multiple modules, such as VRMs, to primary system board 303. In some instances, one or more connection sets of solder balls 325 may be mounted to a circuit board of the PSU 341, such as for connecting modules used for regulating the voltage being supplied to the primary system board 303.

Now referring to FIG. 4A, and example of concentric rings 420 is illustrated. In this example, concentric rings 420 include three solid rings, 421, 422 and 423. Concentric rings 420 may include concentric rings 120/220 described in reference to FIGS. 1 and 2. Referring to FIG. 4B, solder balls 425 arranged in a configuration to receive the concentric rings 420 of FIG. 4A is presented. Solder balls 425 may include solder balls 125/225 and 325 described in reference to FIGS. 1, 2 and 3. In this example, solder balls 425 include three sets of dotted rings 426, 427 and 428. In an example, the connection of concentric ring 421 with solder rings 426 may be used for transferring 12V power to a voltage regulator module. In the example, the connection of concentric ring 422 with solder balls 427 may be used for a ground connection, while the connection of concentric ring 423 and solder rings 428 may be used for transferring 3.3 v power from the voltage regulator module. It should be noted that these connections are provided solely as examples for ease of understanding. As such, one of ordinary skill in the art would appreciate the many other types of connections that can be included with the connection of concentric rings 420 with solder balls 425. It should also be noted that this configuration of three solid rings 421, 422 and 423 allows for installation of a module, which the concentric rings are a part of, in multiple orientations. As such, the connections between the concentric rings 420 and solder balls 425 may be established when the concentric rings 420 are aligned with most or all of the solder balls 425.

In this example, the connection of concentric rings 420 with solder balls 425 is maintained through the attachment of attachment feature 410 to attachment feature 415. In the example of FIGS. 4A and 4B, the attachment features 410 and 415 are threaded apertures configured to receive a fastener.

Now referring to FIG. 5A, another example of concentric rings 520 is presented. In this example, concentric rings 520 includes two solid concentric rings 521 and 522, and a dotted ring 523. In this example, dotted ring 523 includes eight electrical contacts configured to receive and transmit data signals. For example, some of the signals may include status signals of the microcontroller connected to the concentric rings 520. Concentric rings 520 may be an implementation of concentric rings 120/220 described in reference to FIGS. 1 and 2. FIG. 5B illustrates a configuration of solder balls 525 for aligning with concentric rings 520 of FIG. 5A. Solder balls 525 may be an implementation of solder balls 125/225 and 325 described in reference to FIGS. 1, 2 and 3. Solder balls 525 include dotted rings forming a set of solder balls 526, 527 and 528. In this example configuration, solder balls 526 are configured to connect with concentric rings 521 and solder balls 527 are configured to connect with concentric rings 522, while each solder ball of set of solder balls 528 are configured to align with each electrical contact of dotted ring 523. For example, dotted rings 523 may be used for transmitting signals to a primary system board. As such, each electrical contact of dotted ring 523 are aligned with a respective solder ball of set of solder balls 528 for transmitting the signals to an information processing system. In an example, the signals may include feedback signals such as a power good (PG) signal used for indicating that output voltage is within a desirable range.

FIGS. 5A and 5B include attachments features 510 and 515 in the form of threaded apertures used with a fastener, similar to described in reference to FIGS. 4A and 4B. FIGS. 5A and 5B also include keying hole 511 and keying pin 516, respectively. As described above, each electrical contact of dotted ring 523 must align with each solder ball of set of solder balls 528 as to transmit signals. As such, unlike the example of FIGS. 4A and 4B, which allowed for multiple orientations on installation, in this example keying hole 511 and keying pin 516 are matted to each other to secure each of the electrical contacts of dotted ring 523 aligned with each solder ball of set of solder balls 528.

In instances, a method of connecting a Voltage Regulator module to a circuit board of an information processing system will be described. The method includes placing concentric rings of the Voltage Regulator module on sets of solder balls of the circuit board to electrically connect the Voltage Regulator modules to the circuit board. In instances, the method includes aligning each ring of the concentric rings with each set of solder balls. In instances, the set of solder balls is arranged in a dotted ring pattern. In instances, each ring of the concentric rings are solid rings. For example, each solid ring of the concentric rings is placed in alignment with a respective dotted ring set of solder balls arranged. In some instances, one of the rings of the concentric rings may be a dotted ring. In instances, each electrical contact of the dotted rings concentric ring may be configured to connected with a respective solder ball of a set of solder balls and transfer signals between voltage regulator module and the circuit board. For example, each of the electrical contacts of the dotted ring concentric ring may be aligned with a respective solder ball for signal communication. The Voltage Regulator module and information processing system may include, or be an implementation of, Voltage Regulator module 100/200 described in reference to FIGS. 1 and 2, respectively. The information processing system may include, or be an implementation of, Voltage Regulator module 100/200 and information processing system 199/299/399 respectively described in reference to FIGS. 1, 2 and 3.

In instances, the method includes removably attaching the Voltage Regulator modules to circuit board using attachment features. In instances, voltage regulator module may include removably attaching a first attachment feature of the voltage regulator module to a second attachment feature of the circuit board. In an example, first and second attachment features may be threaded apertures configured to receive a fastener. In this example, removably attaching the Voltage Regulator module to the circuit board includes fastening the fasteners through the threaded apertures into Voltage Regulator module is secured to the circuit board. In an example, the first attachment feature may be a clamp while the second attachment may be a protrusion that receives the clamp, where in this example the voltage regulator module is removably attached to the circuit board by engaging the clamp to the protrusion as to secure the voltage regulator module to the circuit board in an electrically connected position.

In instances where one of the concentric rings is a dotted ring, the method may include engaging a keying hole of the Voltage Regulator module with a keying pin of the circuit board. In some instances, both voltage regulator module and circuit board include a respective keying hole, where both keying holes are engaged with a keying pin. It should be noted that in either configuration, the engagement of the keying pin with keying hole(s) is used to maintain each electrical contact of the dotted ring aligned with a respective solder ball of the circuit board.

In the description above, various types of electronic circuitry are described. As used herein, “electronic” is intended to be understood broadly to include all types of Circuits utilizing electricity, including digital and analog circuitry, direct current (DC) and alternating current (AC) circuits, and circuits for converting electricity into another form of energy and circuits for using electricity to perform other functions. In other words, as used herein there is no distinction between “electronic” circuits and “electrical” circuits.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. A voltage regulator module comprising:
a printed circuit board (PCB);
voltage regulator components mounted to a first face of the PCB;
at least one attachment feature configured to removably attach the voltage regulator module to a circuit board of an information processing system; and
electrical contacts formed on a second face of the PCB in concentric rings and electrically connected to the voltage regulator components, wherein the concentric rings are configured to removably contact and electrically connect to a plurality of solder balls on a face of the circuit board.

2. The voltage regulator module of claim 1, wherein the concentric rings are configured to transfer electrical power signals from the solder balls.

3. The voltage regulator module of claim 2, wherein at least one concentric ring of the concentric rings is configured to transfer data signals.

4. The voltage regulator module of claim 1, wherein the circuit board is one of a system board or a peripheral circuit board of the information processing system.

5. The voltage regulator module of claim 1, wherein the circuit board is a system board with a central processing unit (CPU) mounted thereto, and wherein the voltage regulator components are configured to receive power from a power supply unit, regulate the power, and provide the regulated power to the CPU.

6. The voltage regulator module of claim 1, wherein the concentric rings have a circular profile.

7. The voltage regulator module of claim 1, wherein the concentric rings have a non-circular profile.

8. The voltage regulator module of claim 1, wherein the at least one attachment feature comprises a clamp, a clip or a fastener.

9. The voltage regulator module of claim 1, wherein the attachment feature is located at the center of the one or more concentric rings.

10. A computing system, comprising:
a chassis comprising a base;
a system board supported by the base, wherein the system board comprises solder balls on a face of the system board and a first attachment feature; and
a voltage regulator module comprising:
a printed circuit board (PCB);
voltage regulator components mounted to a first face of the PCB;
a second attachment feature removably attached to the first attachment feature of the system board; and
electrical contact pads formed on a second face of the PCB in concentric rings and electrically connected to the microcontroller, wherein the concentric rings are in removable contact and electrically connected to the solder balls on the face of the system board.

11. The system of claim 10, wherein the concentric rings are configured to transfer electrical power signals from the solder balls.

12. The system of claim 11, wherein at least one concentric ring of the concentric rings is configured to transfer data signals.

13. The system of claim 12, wherein the concentric rings have a circular profile.

14. The system of claim 12, wherein the concentric rings have a squared profile.

15. The system of claim 12, wherein the concentric rings are flush with the surface of the voltage regulator module.

16. The system of claim 15, wherein solder balls protrude from the system board.

17. A primary system board for an information processing device, comprising:
a printed circuit board (PCB);
a processor socket mounted to the PCB;
power circuitry formed in the PCB, the power circuitry comprising:
a supply voltage power rail and a ground power rail;
a plurality of electrical contacts at a face of the PCB including a first set of electrical contacts electrically connected to the supply voltage power rail and a second set of electrical contacts electrically connected to the ground power rail; and
a plurality of solder balls formed on the electrical contacts,
wherein the first set of electrical contacts are arranged in a first ring, and
wherein the second set of electrical contacts are arranged in a second ring concentric with the first ring.

18. The primary system board of claim 17, wherein the PCB comprises a communication trace.

19. The primary system board of claim 18, wherein the plurality of electrical contacts at the face of the PCB includes a third set of electrical contacts connected to the communication trace.

20. The primary system board of claim 19, wherein the third set of electrical contacts are arranged in a third ring concentric with the second ring.
